(19) United States
(12) Patent Application Publication
(10) Pub. No.: US 2009/0239148 A1
(43) Pub. Date: Sep. 24, 2009

(54) HIGH VOLTAGE CATHODE COMPOSITIONS

(75) Inventor: Junwei Jiang, Woodbury, MN (US)

Correspondence Address: 3M INNOVATIVE PROPERTIES COMPANY, PO BOX 33427, ST. PAUL, MN, 55133-3427, US

(73) Assignee: 3M Innovative Properties Company

(21) Appl. No.: 12/403,388

(22) Filed: Mar. 13, 2009

Related U.S. Application Data
(60) Provisional application No. 61/038,864, filed on Mar. 24, 2008.

(51) Int. Cl. H01M 4/58; H01M 4/50; H01M 4/32; H01M 4/36; B05D 5/12; C23C 14/34

(52) U.S. Cl. 429/221; 429/224; 429/223; 429/231.3; 429/231.95; 429/231.6; 429/231.5; 427/77; 427/569; 204/192.1; 977/811

(57) ABSTRACT

Cathode compositions for lithium-ion electrochemical cells are provided that have excellent stability at high voltages. These materials include a plurality of particles having an outer surface and a lithium electrode material in contact with at least a portion of the outer surface of the particles. The particles includes a lithium metal oxide that includes manganese, nickel, and cobalt, and the lithium electrode material has a recharged voltage that is lower vs. Li/Li⁺ than the recharged voltage of the particles vs. Li/Li⁺. Also included are methods of making the provided compositions.

### RELATED APPLICATIONS

This application claims priority to U.S. Provisional Patent Application, 61/038,864, filed Mar. 24, 2008.

### FIELD

Provided are cathode compositions for lithium-ion electrochemical cells that can have excellent stability at high voltages.

### BACKGROUND

Secondary lithium-ion batteries typically include an anode, an electrolyte, and a cathode that contains lithium in the form of a lithium transition metal oxide. Examples of transition metal oxides that have been used include lithium cobalt dioxide, lithium nickel dioxide, and lithium manganese dioxide.

Attempts have been made to protect certain cathode compositions from reaction with electrolyte. For example, there have been attempts to prevent the dissolution of Mn in spinel cathodes and to prevent the degradation of FeS₂ cathodes during charging or overdischarging. However, these attempts have generally involved cathode active materials that are “fully delithiatable” (fully delithiated during charging of the cell). Unlike “non-fully delithiatable” cathode active materials such as LiCoO₂ (which typically has only half of its lithium removed when charged (for example, to Li_{0.5}CoO₂)), no additional capacity can be obtained with these materials by increasing the voltage range of the charge. Thus, there is no need to stabilize fully delithiatable materials at higher voltages to access extra capacity.

### SUMMARY

There is a need for non-fully delithiatable cathode compositions for rechargeable lithium batteries that are electrochemically stable (for example, stable to oxidative and reductive degradation) at high voltages, that have high capacity, and that can be simply and cost-effectively prepared without the need for multiple process steps.

In one aspect, a cathode composition is provided that includes a plurality of particles having an outer surface and a layer comprising a lithium electrode material in contact with at least a portion of the outer surface of the particles, wherein the particles include a lithium metal oxide that includes at least one metal selected from manganese, nickel, and cobalt, and wherein the lithium electrode material has a recharged voltage vs. Li/Li⁺ that is less than the recharged voltage of the particles vs. Li/Li⁺.

In another aspect, a method of making a cathode composition is provided that includes providing a plurality of particles having an outer surface, providing a lithium electrode material, and coating the lithium electrode material on the particles to form a layer comprising a lithium electrode material in contact with at least a portion of the outer surface of the particles, wherein the particles comprise a lithium metal oxide that includes at least one metal selected from manganese, nickel, and cobalt, and wherein the lithium electrode material has a recharged voltage vs. Li/Li⁺ that is less than the recharged voltage of the particles vs. Li/Li⁺.

Finally, in yet another aspect, a method of making a cathode is provided that includes providing a current collector in the form of a metallic film, coating a plurality of particles having an outer surface on the current collector, and coating a lithium electrode material on the particles so that the lithium electrode material is in contact with at least a portion of the outer surface of the particles, wherein the particles comprise a lithium metal oxide that includes at least one metal selected from manganese, nickel, and cobalt, and wherein the lithium electrode material has a recharged voltage vs. Li/Li⁺ that is less than the recharged voltage of the particles vs. Li/Li⁺.

As used herein:

the singular forms “a”, “an”, and “the” encompass plural embodiments, unless the context clearly dictates otherwise;

“lithiate” and “lithiation” refer to a process for adding lithium to an electrode material;

“delithiate” and “delithiation” refer to a process for removing lithium from an electrode material;

“charge” and “charging” refer to a process for providing electrochemical energy to a cell;

“discharge” and “discharging” refer to a process for removing electrochemical energy from a cell, e.g., when using the cell to perform desired work;

“positive electrode” refers to an electrode (often called a cathode) where electrochemical reduction and lithiation occurs during a discharging process; and

“negative electrode” refers to an electrode (often called an anode) where electrochemical oxidation and delithiation occurs during a discharging process.

The provided cathode compositions and methods can produce electrodes and lithium-ion electrochemical cells that operate at high average voltages (above about 3.7 V vs. Li/Li⁺ without substantial capacity loss during cycling, which can be due to electrolyte oxidation at the surface of the cathode. Substantial capacity loss can be as much as 20%, or even as much as 30%. For example, electrodes made with the provided cathode compositions and incorporated into a lithium-ion electrochemical cell can maintain at least 90% of their initial reversible specific capacity after 100 charge/discharge cycles from about 4.6 V to about 2.5 V vs. Li/Li⁺. Additionally cathodes made with the provided compositions can deliver high capacity of up to about 180 mAh/g at 4.6 V vs. Li/Li⁺ or even higher depending upon composition and cycling conditions.

The above summary is not intended to describe each disclosed embodiment of every implementation of the present invention. The brief description of the drawing and the detailed description which follows more particularly exemplify illustrative embodiments.

### BRIEF DESCRIPTION OF THE DRAWINGS

FIGS. 1A-1C is a schematic relating to an embodiment.

FIGS. 2A-2C are cross-sectional views relating to three different embodiments.

FIG. 3A is a scanning electron microprobe image of a comparative cathode material.

FIG. 3B is a scanning electron microprobe image of an embodiment of the provided cathode materials.

FIG. 4 is a graph of the specific discharge capacity vs. cycle number of a comparative cathode material and an embodiment.

FIG. 5 is a graph of the specific discharge capacity v. cycle number of a comparative cathode material and another embodiment.

### DETAILED DESCRIPTION

In the following description, reference is made to the accompanying set of drawings that form a part of the description hereof and in which are shown by way of illustration several specific embodiments. It is to be understood that other embodiments are contemplated and may be made without departing from the scope or spirit of the present invention. The following detailed description, therefore, is not to be taken in a limiting sense.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein. The use of numerical ranges by endpoints includes all numbers within that range (e.g. 1 to 5 includes 1, 1.5, 2, 2.75, 3, 3.80, 4, and 5) and any range within that range.

A cathode composition is provided that includes a plurality of particles having an outer surface and a lithium electrode material in contact with at least a portion of the outer surface of the particles, wherein the particles include a lithium metal oxide that has at least one metal selected from manganese, nickel, and cobalt, and wherein the lithium electrode material has a recharged voltage vs. Li/Li⁺ that is less than the recharged voltage of the particles vs. Li/Li⁺. Functionally, the particles, preferably, include lithium metal oxides that work better as stable cathode materials at high voltages, such as voltages above 4.2 V. The lithium metal oxide can be a replacement for LiCoO₂ in traditional lithium-ion electrochemical cells and can adopt the O3 layered structure that can be desirable for efficient lithiation and delithiation. Spinel structures are also within the scope of the structure of the provided cathodes to the extent that materials with spinel structures are able to delithiate and lithiate without significant loss of capacity.

In some embodiments, the provided cathode materials can have the formula, Li[LiₓMnₐNi_{b}Co_{c}]O₂, wherein −0.4≦x≦0.6, x+a+b+c=1, and at least one of a, b, or c is greater than zero, and can be prepared by a number of methods and can exhibit good cell performance and appear to be much less reactive with electrolytes at high temperatures compared to LiCoO₂ when charged to a high voltage. Suitable lithium metal oxide materials are described, for example, in U.S. Pat. No. 6,964,828 (Lu et al.); U.S. Pat. Publ. Nos. 2004/0179993 and 2006/0159994 (both Dahn et al.); U.S. Pat. No. 7,211,237 and U.S. Pat. Publ. No. 2007/0202407 (both Eberman et al.); and U.S. Pat. Publ. No. 2006/0147798 and U.S. Pat. No. 6,680,145 (both Obrovac et al.). In some embodiments, the lithium metal oxide can have the formula Li[LiₓMnₐNi_{b}Co_{c}]O₂ where −0.4<x<0.6, each of the values of a, b, and c are greater than 0.02 and less than 0.96, and x+a+b+c=1. In some embodiments, the lithium metal oxide can be selected from a formula wherein the values of a, b, and c are about 0.33; the values of a and b are about 0.5 and the value of c is about zero; the values of a and b are about 0.42 and the value of c is about 0.16; and the value of a is about 0.5, the value of b is about 0.3 and the value of c is about 0.2. In some embodiments, the lithium metal oxide can have the formula, LiMn_{1/3}Ni_{1/3}Co_{1/3}O₂.

In some embodiments, the lithium metal oxide compositions can preferably adopt an O3 or α-NaFeO₂ type layered structure that can be desirable for efficient lithiation and delithiation. These materials are well known in the art and are disclosed, for example, in U.S. Pat. Nos. 5,858,324; 5,900,385 (both to Dahn et al.); and 6,964,828 (Lu et al.). In some embodiments, the provided cathode compositions can include transition metals selected from manganese (Mn), nickel (Ni), and cobalt (Co). The amount of Mn can range from greater than 0 to about 80 mole percent (mol %), from about 20 mol % to about 80 mol %, or from about 30 mol % to about 36 mol % based upon the total mass of the cathode composition, excluding lithium and oxygen. The amount of Ni can range from greater than 0 to about 75 mol %, from about 20 mol % to about 65 mol %, or from about 46 mol % to about 52 mol % of the cathode composition, excluding lithium and oxygen. The amount of Co can range from greater than 0 to about 88 mol %, from about 20 mol % to about 88 mol %, or from about 15 mol % to about 21 mol % of the composition, excluding lithium and oxygen. In some embodiments, the lithium metal oxide can comprise a composition having the formula, Li[Li_{y}MnₘNiₙCoₚM¹_{q}M²ᵣ]O₂, wherein M¹ and M² are different metals selected from Group 2 and Group 13 elements and wherein at least one of a, b, and c>0, and wherein y+m+n+p+q+r=1; −0.5≦y≦0.2; 0≦m≦0.80; 0≦n≦0.75; 0≦p≦0.88; 0.02≦q+r≦0.30; and each of q and r>0. Preferred compositions of these embodiments can have M¹ and M² selected from aluminum, boron, calcium, and magnesium as disclosed in, for example, U.S. Ser. No. 61/023,447, filed Jan. 25, 2008. More preferred compositions of these embodiments can have M¹ and M² consisting essentially of aluminum and magnesium. In some embodiments, the lithium metal oxide can comprise about 80 mol % nickel, about 15 mol % cobalt, and about 5 mol % aluminum.

In some other embodiments, the lithium metal oxides can be aluminum-doped lithium metal oxides as disclosed, for example, in U.S. Pat. Publ. No. 2006/0068289; lithium cobalt oxide with a lithium buffer material as disclosed, for example, in U.S. Pat. Publ. No. 2007/0218363; nickel-based lithium transition metal oxides as disclosed, for example, in U.S. Pat. Publ. No. 2006/0233696; or lithium transition metal oxides with a gradient of metal compositions as disclosed, for example, in U.S. Pat. Publ. No. 2006/0105239. All of these disclosures are to Paulsen et al.

The lithium metal oxide can be in the form of a single phase having an O3 (α-NaFeO₂) crystal structure and can comprise particles that include transition metal grains having a grain size no greater than about 50 nm and lithium-containing grains selected from lithium oxides, lithium sulfides, lithium halides, and combinations thereof. The average diameter of particles of the mixed metal oxide materials can be from about 2 μm to about 25 μm.

The provided cathode compositions include a lithium electrode material in contact with at least a portion of the outer surface of the lithium metal oxide particles. By contact it is meant that the lithium electrode material can be physically touching the particles and remains in contact with the particles by chemical bonding. Alternatively, the lithium electrode material can be close enough to the particles to have an electronic interaction with the particles such as, for example, an electrostatic attraction. The lithium electrode material can form a physical or electronic barrier that can retard or prevent the particles from interacting with, for example, the electrolyte in an electrochemical cell. The lithium electrode material can comprise a continuous or discontinuous layer in contact with the lithium metal oxide particles. The layer can contain discrete particulates such as nanoparticles or the layer can be relatively smooth and continuous or discontinuous.

The provided cathode compositions can include a lithium electrode material in contact with at least a portion of the outer surface of the particles. The lithium electrode material can have a recharged voltage vs. Li/Li⁺ that is less than the recharged voltage of the particles vs. Li/Li⁺. When used with respect to a positive electrode of a lithium-ion cell, “recharged potential” refers to a value in volts relative to Li/Li⁺, measured by constructing a cell containing the positive electrode, a lithium metal negative electrode, and an electrolyte; carrying out charge/discharge cycling; and observing the potential at which the positive electrode becomes delithiated during the first charge cycle to a lithium level corresponding to at least 90% of the available recharged cell capacity. For some positive electrodes (e.g., LiFePO₄), this lithium level can correspond to substantially complete delithiation. For other positive electrodes (e.g., some electrodes having a layered lithium-containing structure such as lithium metal oxides), this lithium level can correspond to partial delithiation. For example, LiCoO₂ has a recharged potential vs. Li/Li⁺ of about 4.3 V. Lithium metal oxides can have a recharged potential of from about 4.2 V to about 4.4 V vs. Li/Li⁺. The layer of lithium electrode material can have good stability on the surface of the particles and can suppress the electrolyte oxidation reaction resulting in improved cycling performance when the cathode material is fabricated into an electrode and incorporated into a lithium-ion electrochemical cell. In some embodiments, the lithium electrode materials are selected from LiFePO₄, Li₄Ti₅O₁₂, Li₂FeS₂, LiV₆O₁₃, and combinations thereof. In other embodiments, LiFePO₄, Li₄Ti₅O₁₂, and combinations thereof are preferred. In some embodiments, lithium metal oxides, such as those disclosed above, can be used as the lithium electrode materials if they are coated onto particles of lithium metal oxides that have a higher recharged potential vs. Li/Li⁺ than the lithium metal oxides used as the as the lithium electrode materials. For example, LiCoO₂ (with a recharged voltage of about 4.3 V vs. Li/Li⁺) can be used as a lithium electrode material for particles of LiNi_{0.5}Mn_{1.5}O₄ (which has a recharged potential of about 4.7 V vs. Li/Li⁺).

In some embodiments, the provided cathode compositions can have high specific capacity (mAh/g) retention when made into a cathode, incorporated into a lithium ion battery, and cycled through multiple charge/discharge cycles. For example, in some embodiments the provided cathode compositions can have a specific capacity of greater than about 130 mAh/g, greater than about 140 mAh/g, greater than about 150 mAh/g, greater than about 160 mAh/g, greater than about 170 mAh/g, or even greater than about 180 mAh/g. In other embodiments the provided cathode compositions can maintain high specific capacity after 50, after 75, after 90, after 100, or even more charging and discharging cycles at rates of C/4 when the battery is cycled between about 2.5 V and about 4.6 V vs. Li/Li⁺ and the temperature is maintained at about room temperature (25° C.). Furthermore, in some embodiments, the cell can maintain at least 70%, at least 80%, at least 90%, or even at least 95% of its initial reversible specific capacity after 100 charge/discharge cycles from about 4.6 V to about 2.5 V vs. Li/Li⁺ at a rate of C/4. In some embodiments it is preferred to do the initial cycling for the initial one or two cycles at a slower rate such as C/10 or C/5 to allow delithiation of the cathode to the largest extent possible at the beginning of the cycling, thus reducing loss due to irreversible capacity in later cycles.

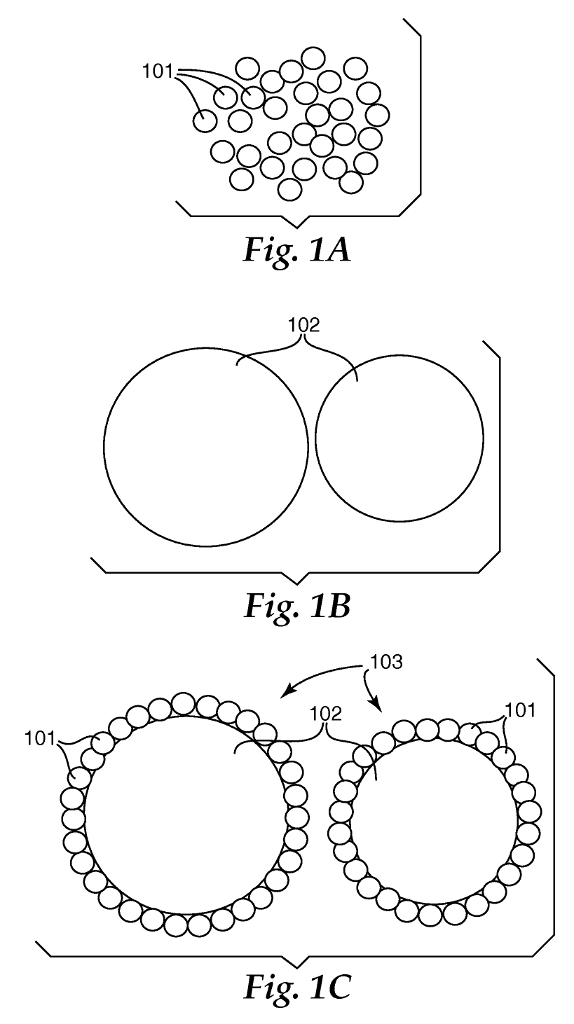

In another aspect, a method of making a cathode composition is provided that includes providing a plurality of particles having an outer surface, providing a lithium electrode material, and coating the lithium electrode material on the particles to form a layer comprising a lithium electrode material in contact with at least a portion of the outer surface of the particles, wherein the particles comprise a lithium metal oxide that includes at least one metal selected from manganese, nickel, and cobalt, and wherein the lithium electrode material has a recharged voltage vs. Li/Li⁺ that is less than the recharged voltage of the particles vs. Li/Li⁺. The methods that can be used to coat the lithium electrode materials on the particles include milling, dispersion coating, knife coating, gravure coating, vapor coating and various vacuum coating techniques. An embodiment of this method is illustrated diagrammatically in FIGS. 1A-1C. Small particulates (preferably nanoparticles) of lithium electrode material 101 (FIG. 1A) are mixed with a plurality of particles 102 of lithium metal oxide (FIG. 1B) to form a mixture. The mixture is then place in a mill, such as a planetary micromill, and is milled. The milling can cause the nanoparticles 101 to form a layer on the lithium metal oxide particles 102 as shown in FIG. 1C. The composite particles 103 can be used to make the provided cathode compositions. Other mills that can be used for this process include, for example, various types of ball mills. This milling process can be particularly useful if the average diameter of the lithium metal oxide particles is much greater than that of the particulates of the lithium electrode material. By much greater than it is meant that the average diameter of the lithium metal oxide particles is at least 5 times, at least 10 times, at least 100 times, or even at least 1000 times that of the average diameter of the lithium electrode material. This method is referred to herein as the “coating process by milling” and it results in a plurality of lithium metal oxide particles with a layer of lithium electrode materials as shown in FIG. 1C. In some embodiments, the lithium electrode material includes nanoparticles that include LiFePO₄. In these embodiments, milling can be performed preferably by using a dry milling technique, that is, one where there substantially no liquid present during milling. By substantially no liquid present it is meant that there is not enough liquid to suspend the particles in a slurry or form a dispersion.

In another embodiment, a method of making a cathode composition is provided that includes providing a lithium electrode material, dispersing the material in a liquid, adding a plurality of particles that include a lithium metal oxide to form a dispersion, and heating the dispersion so as to remove the liquid, wherein the lithium electrode material has a recharged voltage vs. Li/Li⁺ that is less than the recharged voltage of the particles vs. Li/Li⁺, and wherein the mixed metal oxide comprises manganese, nickel, and cobalt. This method, referred to herein as the “sol-gel coating process”, is described in the paper by Qiong-yu Lai et al., Materials Chemistry and Physics, 94 (2005) 382-387. This method can be very useful for making lithium cobalt oxide particles that have a layer of, for example, Li₄Ti₅O₁₂ thereon. Using this method, a sol-gel synthesis of Li₄Ti₅O₁₂ can be performed using citric acid as a chelating agent and lithium carbonate and tetrabutyl titanate as the reagents. After addition of the reagents and chelating agent, lithium metal oxide particles can be added and stirred constantly for a number of hours on a hot plate (for example, at 50° C.). During this process a sol gel can form and then can deposit as a layer on the lithium metal oxide particles as the alcohol solvent evaporates.

To make a cathode from the provided cathode compositions, the provided cathodes composition, any selected additives such as binders, conductive diluents, fillers, adhesion promoters, thickening agents for coating viscosity modification such as carboxymethylcellulose, and other additives known by those skilled in the art can be mixed in a suitable coating solvent such as water or N-methylpyrrolidinone (NMP) to form a coating dispersion or coating mixture. The coating dispersion or coating mixture can be mixed thoroughly and then applied to a foil current collector by any appropriate coating technique such as knife coating, notched bar coating, dip coating, spray coating, electrospray coating, or gravure coating. Cathodes made from the provided cathode compositions can include a binder. Exemplary polymer binders include polyolefins such as those prepared from ethylene, propylene, or butylene monomers; fluorinated polyolefins such as those prepared from vinylidene fluoride monomers; perfluorinated polyolefins such as those prepared from hexafluoropropylene monomer; perfluorinated poly(alkyl vinyl ethers); perfluorinated poly(alkoxy vinyl ethers); aromatic, aliphatic, or cycloaliphatic polyimides, or combinations thereof. Specific examples of polymer binders include polymers or copolymers of vinylidene fluoride, tetrafluoroethylene, and propylene; and copolymers of vinylidene fluoride and hexafluoropropylene. Other binders that can be used in the cathode compositions of this disclosure include lithium polyacrylate which has been shown to have increased capacity retention and cycle life with lithium metal oxide cathodes as disclosed, for example, in co-owned application, U.S. Pat. App. Publ. No. 2008/0187838 A1 (Le et al.). Lithium polyacrylate can be made from poly(acrylic acid) that is neutralized with lithium hydroxide. U.S. Pat. App. Publ. No. 2008/0187838 A1 (Le et al.) discloses that poly(acrylic acid) includes any polymer or copolymer of acrylic acid or methacrylic acid or their derivatives where at least 50 mol %, at least 60 mol %, at least 70 mol %, at least 80 mol %, or at least 90 mol % of the copolymer is made using acrylic acid or methacrylic acid. Useful monomers that can be used to form these copolymers include, for example, alkyl esters of acrylic or methacrylic acid that have alkyl groups with 1-12 carbon atoms (branched or unbranched), acrylonitriles, acrylamides, N-alkyl acrylamides, N,N-dialkylacrylamides, hydroxyalkylacrylates, and the like.

Embodiments of the provided cathode compositions can also include an electrically conductive diluent that can facilitate electron transfer from the powdered cathode composition to a current collector. Electrically conductive diluents include, but are not limited to, carbon (e.g., carbon black for negative electrodes and carbon black, flake graphite and the like for positive electrodes), metal, metal nitrides, metal carbides, metal silicides, and metal borides. Representative electrically conductive carbon diluents include carbon blacks such as SUPER P and SUPER S carbon blacks (both from MMM Carbon, Belgium), SHAWANIGAN BLACK (Chevron Chemical Co., Houston, Tex.), acetylene black, furnace black, lamp black, graphite, carbon fibers and combinations thereof.

In some embodiments, the cathode compositions can include an adhesion promoter that promotes adhesion of the cathode composition and/or electrically conductive diluent to the binder. The combination of an adhesion promoter and binder can help the cathode composition better accommodate volume changes that can occur in the powdered material during repeated lithiation/delithiation cycles. Binders can offer sufficiently good adhesion to metals and alloys so that addition of an adhesion promoter may not be needed. If used, an adhesion promoter can be made a part of a lithium polysulfonate fluoropolymer binder (e.g., in the form of an added functional group), such as those disclosed in U.S. Ser. No. 60/911,877 (Pham), can be a coating on the powdered material, can be added to the electrically conductive diluent, or can be a combination thereof. Examples of useful adhesion promoters include silanes, titanates, and phosphonates as described in U.S. Pat. No. 7,341,804 (Christensen).

In yet another embodiment, a method of making a cathode is provided that includes providing a current collector in the form of a metallic film, coating a plurality of particles having an outer surface on the current collector, and coating a lithium electrode material on the particles so that the lithium electrode material is in contact with at least a portion of the outer surface of the particles, wherein the particles comprise a lithium metal oxide that includes at least one metal selected from manganese, nickel, and cobalt, and wherein the lithium electrode material has a recharged voltage vs. Li/Li⁺ that is less than the recharged voltage of the particles vs. Li/Li⁺. Embodiments relating to this method are illustrated in

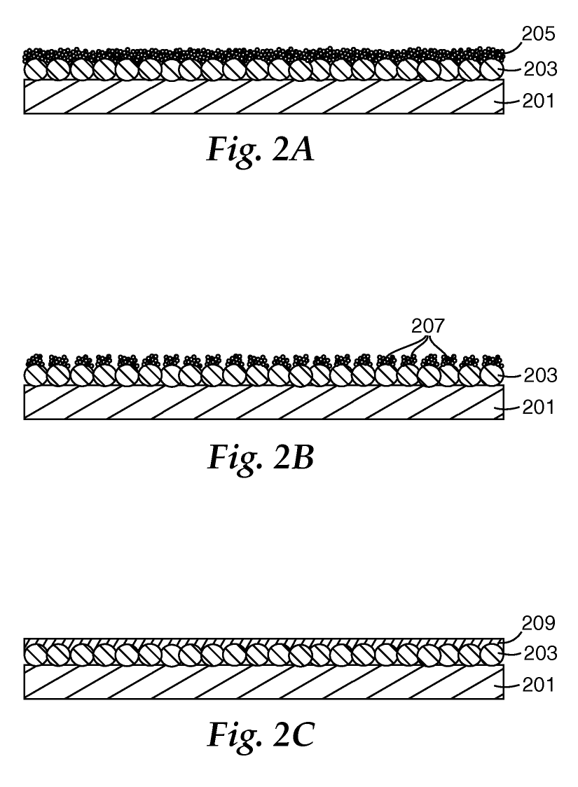

FIGS. 2A-2B. In the embodiment illustrated in FIG. 2A, current collector 201 has a layer of a plurality of particles 203 coated upon it. A thin, continuous layer 205 that includes a lithium electrode material nanoparticles has been coated on top of layer 201. The embodiment illustrated in FIG. 2B is similar to that illustrated in FIG. 2A except that the lithium electrode material in this embodiment 207 is deposited in such as manner as to form a discontinuous layer of “islands” of material on the particles. FIG. 2C illustrates yet another embodiment in which a thin, continuous layer of lithium electrode material 209 is coated onto a plurality of particles 203 that have been deposited on current collector 201. The coating can be by vapor or sputter coating or coating of a dispersion in a liquid, drying the liquid, and coalescing the dispersion by, for example, heating the coating. The current collectors can be typically thin foils of conductive metals such as, for example, aluminum, stainless steel, or nickel foil. The slurry can be coated onto the current collector foil and then allowed to dry in air followed usually by drying in a heated oven, typically at about 80° C. to about 300° C. for about an hour to remove all of the solvent.

Cathodes made from the provided cathode compositions can be combined with an anode and an electrolyte to form a lithium-ion electrochemical cell or a battery from two or more electrochemical cells. Examples of suitable anodes can be made from compositions that include lithium, carbonaceous materials, silicon alloy compositions and lithium alloy compositions. Exemplary carbonaceous materials can include synthetic graphites such as mesocarbon microbeads (MCMB) (available from E-One Moli/Energy Canada Ltd., Vancouver, BC), SLP30 (available from TimCal Ltd., Bodio Switzerland), natural graphites and hard carbons. Useful anode materials can also include alloy powders or thin films. Such alloys may include electrochemically active components such as silicon, tin, aluminum, gallium, indium, lead, bismuth, and zinc and may also comprise electrochemically inactive components such as transition metal silicides and transition metal aluminides. Useful alloy anode compositions can include alloys of tin or silicon such as Sn—Co—C alloys, Si₆₀Al₁₄Fe₈TiSn₇Mm₁₀ and Si₇₀Fe₁₀Ti₁₀C₁₀ where Mm is a Mischmetal (an alloy of rare earth elements). Metal alloy compositions used to make anodes can have a nanocrystalline or amorphous microstructure. Such alloys can be made, for example, by sputtering, ball milling, rapid quenching or other means. Useful anode materials also include metal oxides such as Li₄Ti₅O₁₂, WO₂, SiO₂, tin oxides, or metal sulfites, such as TiS₂ and MoS₂. Other useful anode materials include tin-based amorphous anode materials such as those disclosed in U.S. Pat. Appl. No. 2005/0208378 (Mizutani et al.).

Exemplary silicon alloys that can be used to make suitable anodes include compositions that comprise from about 65 to about 85 mol % Si, from about 5 to about 12 mol % Fe, from about 5 to about 12 mol % Ti, and from about 5 to about 12 mol % C. Additional examples of useful silicon alloys include compositions that include silicon, copper, and silver or silver alloy such as those discussed in U.S. Pat. Publ. No. 2006/0046144 A1 (Obrovac et al.); multiphase, silicon-containing electrodes such as those discussed in U.S. Pat. Publ. No. 2005/0031957 (Christensen et al.); silicon alloys that contain tin, indium and a lanthanide, actinide element or yttrium such as those described in U.S. Pat. Publ. Nos. 2007/0020521, 2007/0020522, and 2007/0020528 (all to Obrovac et al.); amorphous alloys having a high silicon content such as those discussed in U.S. Pat. Publ. No. 2007/0128517 (Christensen et al.); and other powdered materials used for negative electrodes such as those discussed in U.S. Pat. Appl. Publ. No. 2007/0269718 A1 (Krause et al.) and PCT Intl. Publ. No. WO 2007/044315 (Krause et al.). Anodes can also be made from lithium alloy compositions such as those of the type described in U.S. Pat. Nos. 6,203,944 and 6,436,578 (both to Turner et al.) and in U.S. Pat. No. 6,255,017 (Turner).

Provided electrochemical cells can contain an electrolyte. Representative electrolytes can be in the form of a solid, liquid, gel or a combination thereof. Exemplary solid electrolytes include polymeric media such as polyethylene oxide, polytetrafluoroethylene, polyvinylidene fluoride, fluorine-containing copolymers, polyacrylonitrile, combinations thereof and other solid media that will be familiar to those skilled in the art. Examples of liquid electrolytes include ethylene carbonate, propylene carbonate, dimethyl carbonate, diethyl carbonate, ethyl-methyl carbonate, butylene carbonate, vinylene carbonate, fluoroethylene carbonate, fluoropropylene carbonate, γ-butyrolactone, methyl difluoroacetate, ethyl difluoroacetate, dimethoxyethane, diglyme (bis(2-methoxyethyl)ether), tetrahydrofuran, dioxolane, combinations thereof and other media that will be familiar to those skilled in the art. The electrolyte can be provided with a lithium electrolyte salt. Exemplary lithium salts include LiPF₆, LiBF₄, LiClO₄, lithium bis(oxalato)borate, LiN(CF₃SO₂)₂, LiN(C₂F₅SO₂)₂, LiAsF₆, LiC(CF₃SO₂)₃, and combinations thereof. Exemplary electrolyte gels include those described in U.S. Pat. Nos. 6,387,570 (Nakamura et al.) and 6,780,544 (Noh). The charge carrying media solubilizing power can be improved through addition of a suitable cosolvent. Any suitable cosolvent can be used. Exemplary cosolvents include aromatic materials compatible with lithium-ion cells containing the chosen electrolyte. Representative cosolvents include toluene, sulfolane, dimethoxyethane, combinations thereof and other cosolvents that will be familiar to those skilled in the art. The electrolyte can include other additives that will familiar to those skilled in the art. For example, the electrolyte can contain a redox chemical shuttle such as those described in U.S. Pat. Nos. 5,709,968 (Shimizu), 5,763,119 (Adachi), 5,536,599 (Alamgir et al.), 5,858,573 (Abraham et al.), 5,882,812 (Visco et al.), 6,004,698 (Richardson et al.), 6,045,952 (Kerr et al.), and 6,387,571 (Lain et al.); and in U.S. Pat. Appl. Publ. Nos. 2005/0221168, 2005/0221196, 2006/0263696, and 2006/0263697 (all to Dahn et al.). Particularly preferred are redox chemical shuttles that can be useful for high voltage cathode materials and which are disclosed, for example, in U.S. Ser. No. 12/366,002, filed Feb. 5, 2009.

In some embodiments, lithium-ion electrochemical cells that include provided cathode compositions can be made by taking at least one each of a positive electrode and a negative electrode as described above and placing them in an electrolyte. Typically, a microporous separator, such as CELGARD 2400 microporous material, available from Celgard LLC, Charlotte, N.C., is used to prevent the contact of the negative electrode directly with the positive electrode. This can be especially important in coin cells such as, for example, 2325 coin cells as is well known in the art.

The disclosed electrochemical cells can be used in a variety of devices, including portable computers, tablet displays, personal digital assistants, mobile telephones, motorized devices (e.g., personal or household appliances and vehicles), instruments, illumination devices (e.g., flashlights) and heating devices. One or more electrochemical cells of this invention can be combined to provide battery pack. Further details as to the construction and use of the provided lithium-ion cells and battery packs are familiar to those skilled in the art.

Objects and advantages of this invention are further illustrated by the following examples, but the particular materials and amounts thereof recited in these examples, as well as other conditions and details, should not be construed to unduly limit this invention.

### EXAMPLES

### Electrochemical Cell Preparation

### Thin Film Cathode Electrodes for Electrochemical Tests

Electrodes were prepared as follows: 10% polyvinylidene difluoride (PVDF, Aldrich Chemical Co.) in N-methylpyrrolidinone solution was prepared by dissolving about 10 g PVDF into 90 g of NMP solution. 7.33 g Super-P carbon (MMM Carbon, Belgium), 73.33 g of 10 weight percent (wt %) PVDF in NMP solution, and 200 g NMP were mixed in a glass jar. The mixed solution contained about 2.6 wt % each of PVDF and Super-P carbon in NMP. 5.25 g of the solution was mixed with 2.5 g cathode material using a Mazerustar mixer machine (Kurabo Industries Ltd., Japan) for 3 minutes to form uniform slurry. The slurry was then spread onto a thin aluminum foil on a glass plate using a 0.25 mm (0.010 in.) notch-bar spreader. The coated electrode was then dried in an 80° C. oven for around 30 minutes. The electrode was then put into a 120° C. vacuum oven for 1 hour to evaporate NMP and moisture. The dry electrode contained about 90 wt % cathode material and 5 wt % PVDF and Super P each. The mass loading of the active cathode material was around 8 mg/cm².

### Cell Construction

Coin cells were fabricated with the resulting cathode electrode and Li metal anode in a 2325-size (23 mm diameter and 2.5 mm thickness) coin-cell hardware in a dry room. The separator was a CELGARD 2400 microporous polypropylene film which had been wetted with a 1M solution of LiPF₆ (Stella Chemifa Corporation, Japan) dissolved in a 1:2 volume mixture of ethylene carbonate (EC) (Aldrich Chemical Co.) and diethyl carbonate (DEC) (Aldrich Chemical Co.).

### Coating Processes

### Coating Process by Milling.

A milling coating process is described below to coat material A with a material B that has a much smaller average particle size than material A. 5.00 g of BC-618 cathode material (LiMn_{1/3}Ni_{1/3}Co_{1/3}O₂, available from 3M, St. Paul, Minn.) with an average particle size of 11.0 μm was mixed together with 0.30 g of nano-size LiFePO₄ (Phostech Lithium Inc., Canada) having an average size of 1.5 μm using a Planetary Micromill (Fritsch). The milling was done for 1 hour.

### Coating Process by Sol-Gel

The Sol-gel process was described in the paper by Qiong-yu Lai et al., Materials Chemistry and Physics, 94 (2005) 382-387. 3.71 g of tetrabutyl titanate (TiO(C₄H₉)₄) and 0.348 g of Li₂CO₃ were dissolved together in alcohol solution. 1.285 g of citric acid was added into the mixture solution as a chelating agent. 20.00 g of BC-618 cathode material was mixed with the solution and the mixture was stirred constantly for about 5 hours on the top of a hot plate at about 50° C. During the stirring process, a gel formed and the alcohol was slowly evaporated away. The organic polymer was deposited on surface of the cathode material. The resulted dry cathode mixture was ground gently and then sintered for 12 hours at 850° C. to produce Li₄Ti₅O₁₂.

### Example 1

### LiMn_{1/3}Ni_{1/3}CO_{1/3}O₂ Coated with Approximately 5 wt % Nano-Size LiFePO₄ using the Milling Process

Nano-size LiFePO₄ was coated on the surface of the LiMn_{1/3}Ni_{1/3}CO_{1/3}O₂ cathode particles at about a 6 wt % loading using the milling process described above.

### Example 2

### LiMn_{1/3}Ni_{1/3}CO_{1/3}O₂ Coated with 5 wt % Li₄Ti₅O₁₂ using the Sol-Gel Process

Li₄Ti₅O₁₂ was coated on the surface of the LiMn_{1/3}Ni_{1/3}Co_{1/3}O₂ cathode material using the sol-gel process described above.

### Results

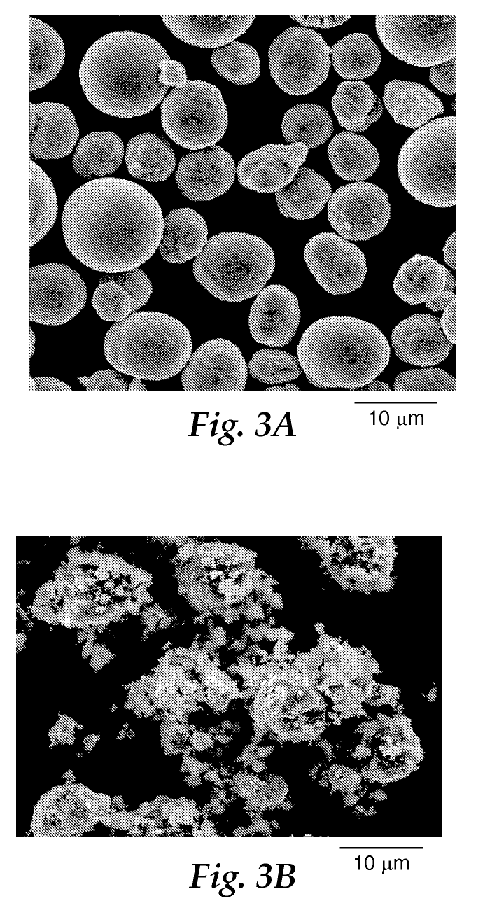

FIGS. 3A and 3B are SEM images of uncoated BC-618 cathode material BC-618 cathode material coated with nano size LiFePO₄ using the milling process. The BC-618 cathode material has an average particle size of about 11.0 μm. Before the coating process, LiMn_{1/3}Ni_{1/3}Co_{1/3}O₂ has a smooth surface as shown in FIG. 3A. After milling process, LiMn_{1/3}Ni_{1/3}Co_{1/3}O₂ surface is covered by nano size LiFePO₄ particles shown in FIG. 3B.

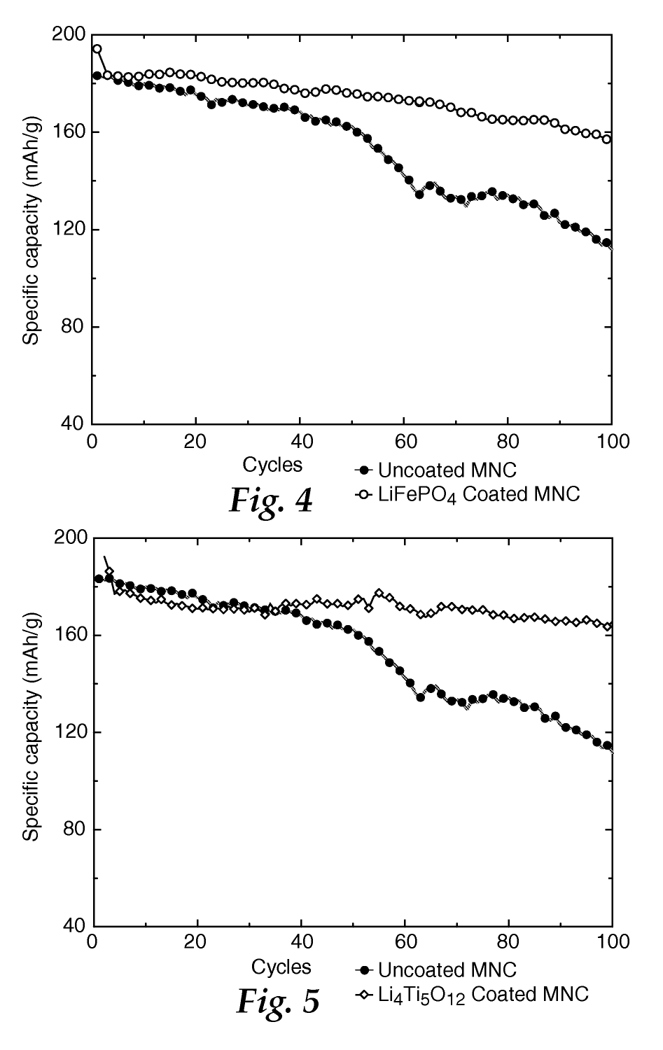

FIG. 4 is a graph that compares the cycling performance of uncoated LiMn_{1/3}Ni_{1/3}Co_{1/3}O₂ versus coated LiMn_{1/3}Ni_{1/3}Co_{1/3}O₂ with nano size LiFePO₄ (Example 1) in 2325 coin cells with a reference Li anode. The coin cells were cycled from 2.5 V to 4.6 V at a low rate of C/10 in the first two cycles. The rate was increased to C/4 in later cycles. The uncoated LiMn_{1/3}Ni_{1/3}Co_{1/3}O₂ had poor capacity retention of around 60% after 100 cycles, compared to excellent capacity retention around 86% for the LiFePO₄ coated material. While not being bound by theory, the data suggests that the LiFePO₄ coating on the LiMn_{1/3}Ni_{1/3}Co_{1/3}O₂ surface greatly decreased the surface reactivity between the charged cathode material and the electrolyte at high voltages in order to maintain the cathode discharge capacity during extended cycling.

FIG. 5 is a graph that compares the cycling performance of uncoated LiMn_{1/3}Ni_{1/3}Co_{1/3}O₂ versus coated LiMn_{1/3}Ni_{1/3}Co_{1/3}O₂ with Li₄Ti₅O₁₂ in 2325 coin cells (Example 2) with a reference Li anode. As in FIG. 2, coated LiMn_{1/3}Ni_{1/3}Co_{1/3}O₂ shows high capacity retention up to 89% at a 4.6 V cutoff voltage after 100 cycles. While not being bound by theory, the data for Examples 1 and 2 suggest that the cathode material cycling performance at high voltages (such as 4.6 V) can be increased by coating the cathode materials with stable Li-ion materials, such as LiFePO₄ or Li₄Ti₅O₁₂.

Various modifications and alterations of this invention will become apparent to those skilled in the art without departing from the scope and principles of this invention, and it should be understood that this invention is not to be unduly limited to the illustrative embodiments set forth hereinabove.

What is claimed is:

1. A cathode composition comprising:
a plurality of particles having an outer surface; and
a layer comprising a lithium electrode material in contact with at least a portion of the outer surface of the particles,
wherein the particles comprise a lithium metal oxide that includes at least one metal selected from manganese, nickel, and cobalt, and wherein the lithium electrode material has a recharged voltage vs. Li/Li⁺ that is less than the recharged voltage of the particles vs. Li/Li⁺.

2. The cathode composition according to claim 1, wherein the lithium metal oxide adopts an O3 structure.

3. The cathode composition according to claim 1, wherein the lithium metal oxide has the formula Li[LiₓMnₐNi_{b}Co_{c}]O₂ where −0.4<x<0.6, each of a, b, and c are greater than 0.02 and less than 0.96, and x+a+b+c=1.

4. The cathode composition according to claim 3, wherein the lithium metal oxide has the formula, Li[LiₓMnₐNi_{b}Co_{c}]O₂, wherein a, b, and c are selected from values wherein a, b, and c are about 0.33; a and b are about 0.5 and c is about zero; a and b are about 0.42 and c is about 0.16; and a is about 0.5, b is about 0.3 and c is about 0.2.

5. The cathode composition according to claim 1, wherein the lithium metal oxide further comprises one or more metals selected from aluminum, boron, calcium, and magnesium.

6. The cathode composition according to claim 5, wherein the one or more metals consist essentially of aluminum and magnesium.

7. The cathode composition according to claim 1, wherein the particles comprise more than one phase.

8. The cathode composition according to claim 1, wherein the lithium electrode material comprises nanoparticles.

9. The cathode composition according to claim 1, wherein the lithium electrode material is selected from LiFePO₄, Li₄Ti₅O₁₂, Li₂FeS₂, LiV₆O₁₃, and combinations thereof.

10. The cathode composition according to claim 9, wherein the lithium electrode material is selected from LiFePO₄, Li₄Ti₅O₁₂, and combinations thereof.

11. The cathode composition according to claim 1, wherein the lithium electrode material comprises a continuous layer.

12. An electrode comprising the cathode composition according to claim 1.

13. An electrochemical cell comprising at least one electrode according to claim 12.

14. The electrochemical cell according to claim 13, wherein the cell maintains at least 90% of its initial reversible specific capacity after 100 charge/discharge cycles from about 4.6 V to about 2.5 volts vs. Li/Li⁺ at a rate of C/4.

15. A battery pack comprising at least two electrochemical cells according to claim 13.

16. An electronic device comprising an electrochemical cell according to claim 13.

17. A method of making a cathode composition comprising:
providing a plurality of particles having an outer surface;
providing a lithium electrode material; and
coating the lithium electrode material on the particles to form a layer comprising a lithium electrode material in contact with at least a portion of the outer surface of the particles,
wherein the particles comprise a lithium metal oxide that includes at least one metal selected from manganese, nickel, and cobalt, and
wherein the lithium electrode material has a recharged voltage vs. Li/Li⁺ that is less than the recharged voltage of the particles vs. Li/Li⁺.

18. The method according to claim 17, wherein coating comprises milling the particles and the lithium electrode material,
wherein the lithium electrode material comprises nanoparticles.

19. The method according to claim 18, wherein milling comprises dry milling.

20. The method according to claim 17, wherein coating further comprises:
dispersing the lithium electrode material in a liquid;
adding the plurality of particles that include a lithium metal oxide to form a dispersion; and
heating the dispersion so as to remove the liquid.

21. A method of making a cathode comprising:
providing a current collector in the form of a metallic film;
coating a plurality of particles having an outer surface on the current collector; and
coating a lithium electrode material on the particles so that the lithium electrode material is in contact with at least a portion of the outer surface of the particles,
wherein the particles comprise a lithium metal oxide that includes at least one metal selected from manganese, nickel, and cobalt, and
wherein the lithium electrode material has a recharged voltage vs. Li/Li⁺ that is less than the recharged voltage of the particles vs. Li/Li⁺.

22. The method according to claim 21, wherein the lithium electrode material is coated using a method selected from spray coating, knife coating, gravure coating, vapor coating, and vacuum coating.

23. The method according to claim 22, wherein vacuum coating comprises sputtering, evaporative coating, and plasma coating.
